(19) United States
(12) Patent Application Publication
(10) Pub. No.: US 2026/0094788 A1
(43) Pub. Date: Apr. 2, 2026

(54) Plasma Processing Apparatus

(71) Applicant: Tokyo Electron Limited, Tokyo (JP)

(72) Inventors: Eiki KAMATA, Yamanashi (JP); Kazushi KANEKO, Yamanashi (JP)

(21) Appl. No.: 19/331,966

(22) Filed: Sep. 17, 2025

(30) Foreign Application Priority Data
Sep. 30, 2024 (JP) 2024-170938

(51) Int. Cl. H01J 37/32

(52) U.S. Cl. CPC H01J 37/32247; H01J 37/32238

(57) ABSTRACT

A plasma processing apparatus comprises a processing chamber, a microwave generator, a microwave radiator, a microwave transmitting window and a resonator array structure. The processing chamber is configured to accommodate a substrate and define a processing space by a ceiling wall, a sidewall, and a bottom wall. The microwave generator is configured to generate microwaves for producing plasma. The microwave radiator is provided above the ceiling wall and configured to radiate the microwaves toward the processing chamber. The microwave transmitting window is formed of a dielectric and provided at a position of the ceiling wall corresponding to the microwave radiator. The resonator array structure is provided in at least one of the ceiling wall and the sidewall and formed by arranging a plurality of resonators that are configured to resonate with a magnetic field component of the microwaves and each having a size smaller than a wavelength of the microwaves.

### CROSS-REFERENCE TO RELATED APPLICATIONS

This application claims priority to Japanese Patent Application No. 2024-170938 filed on Sep. 30, 2024, the entire contents of which are incorporated herein by reference.

### TECHNICAL FIELD

The present disclosure relates to a plasma processing apparatus.

### BACKGROUND

Japanese Laid-open Patent Publication No. 2021-031706 discloses a plasma processing apparatus having a plurality of microwave radiation mechanisms on a ceiling wall of a processing chamber.

### SUMMARY

The present disclosure provides a plasma processing apparatus that can suppress electromagnetic waves propagating along an inner wall of a processing chamber.

A plasma processing apparatus according to one embodiment of the present disclosure comprises a processing chamber configured to accommodate a substrate and define a processing space by a ceiling wall, a sidewall, and a bottom wall, a microwave generator configured to generate microwaves for producing plasma, a microwave radiator provided above the ceiling wall and configured to radiate the microwaves toward the processing chamber, a microwave transmitting window formed of a dielectric and provided at a position of the ceiling wall corresponding to the microwave radiator, and a resonator array structure provided in at least one of the ceiling wall and the sidewall, the resonator array structure being formed by arranging a plurality of resonators that are configured to resonate with a magnetic field component of the microwaves and each having a size smaller than a wavelength of the microwaves.

### BRIEF DESCRIPTION OF THE DRAWINGS

FIG. 1 is a schematic cross-sectional view showing an example of a configuration of a plasma processing apparatus according to the present embodiment.

FIG. 2 is a diagram showing an example of a configuration of a microwave introducing device according to the present embodiment.

FIG. 3 is a diagram showing an example of a microwave radiation mechanism according to the present embodiment.

FIG. 4 is a plan view showing an example of a ceiling wall of a processing chamber according to the present embodiment.

FIG. 5 is a perspective view showing an example of the ceiling wall of the processing chamber according to the present embodiment.

FIG. 6 is a diagram showing an example of the relationship between a traveling direction of electromagnetic waves and a direction of a ring member according to the present embodiment.

FIG. 7 is a diagram showing an example of a configuration of a resonator according to the present embodiment.

FIG. 8 is a diagram showing an example of a configuration of a resonator according to the present embodiment.

FIG. 9 is a diagram showing another example of a configuration of a resonator according to the present embodiment.

FIG. 10 is a diagram showing an example of a cross section of a resonator according to the present embodiment.

FIG. 11 is a diagram showing an example of the arrangement of resonators in a resonator array structure according to the present embodiment.

FIG. 12 is a diagram showing an example of the arrangement of resonators in a resonator array structure according to the present embodiment.

FIG. 13 is a diagram showing an example of the relationship between an S₂₁ value of a resonator and a microwave frequency.

FIG. 14 is a diagram showing an example of a simulation model.

FIG. 15 is an enlarged view showing an example of the vicinity of a sheath of a simulation model.

FIG. 16 is a graph showing an example of the relationship between a relative permeability of a resonator array structure and a power absorbed by plasma.

FIG. 17 is a diagram showing an example of a simulation result obtained when the relative permeability of the resonator array structure is a positive value.

FIG. 18 is a diagram showing an example of a simulation result obtained when the relative permeability of the resonator array structure is a negative value.

FIG. 19 is an enlarged view showing an example of the vicinity of a sheath of a simulation model in the case where a conductive film exists.

FIG. 20 is a graph showing an example of the relationship between a conductivity of a conductive film and a power absorbed by plasma and the conductive film.

FIG. 21 is a graph showing an example of the relationship between a relative permeability of a resonator array structure and a power absorbed by plasma and a conductive film.

FIG. 22 is a diagram showing an example of a simulation result obtained when a conductive film exists and the relative permeability of the resonator array structure is a positive value.

FIG. 23 is a diagram showing an example of a simulation result obtained when a conductive film exists and the relative permeability of the resonator array structure is a negative value.

FIG. 24 is a perspective view schematically showing an example of a sidewall of a processing chamber according to Modification 1.

FIG. 25 is a diagram showing an example of the relationship of a traveling direction of electromagnetic wave, a resonator array structure, and a gas introducing nozzle according to Modification 1.

FIG. 26 is a plan view showing an example of a configuration of a dielectric window and a resonator array structure according to Modification 2, which is viewed from below.

### DETAILED DESCRIPTION

Hereinafter, embodiments of the plasma processing apparatus will be described in detail with reference to the accompanying drawings. Further, the present disclosure is not limited to the following embodiment.

In a plasma processing apparatus using microwaves for plasma excitation, the power of the microwaves supplied into the processing chamber may be increased in order to increase the electron density of the plasma. The electron density of the plasma may increase as the power of the microwaves supplied into the processing chamber increases.

Here, it is known that when the electron density of the plasma reaches a certain upper limit by increasing the power of the microwaves supplied into the processing chamber, the dielectric constant of the space in the processing chamber becomes negative. The upper limit of the electron density is appropriately referred to as “cutoff density.” In addition, the refractive index is known as an index indicating whether or not microwaves can propagate through space. The refractive index N is expressed by the following Eq. (1):

$$N = √ ε √ μ , \qquad Eq . ( 1 )$$

wherein ϵ indicates a dielectric constant, and μ indicates a magnetic permeability.

In general, the magnetic permeability is a positive value. Therefore, when the dielectric constant of the space in the processing chamber becomes a negative value, the refractive index of the space in the processing chamber becomes a pure imaginary number according to the above Eq. (1). Accordingly, microwaves are attenuated and cannot propagate through the space in the processing chamber. As described above, when the plasma electron density reaches the cutoff density, the microwaves cannot propagate in the space in the processing chamber and, thus, the microwave power is not sufficiently absorbed by the plasma. As a result, the increase in the density of the plasma produced in the processing chamber over a wide area is hindered.

Further, in a plasma processing apparatus having a microwave radiator in the ceiling wall of the processing chamber, plasma is generated directly below the ceiling wall. In such a plasma processing apparatus, the surface waves propagating along the plasma interface may spread widely along the ceiling wall. Accordingly, discharge may occur in the gap near the connection portion between the ceiling wall and the sidewall, or in the gas introducing nozzle, or particles may be generated. Therefore, it is expected that the electromagnetic waves propagating along the inner wall of the processing chamber can be suppressed by eliminating the propagation mode of the surface waves in the inner wall of the processing chamber.

### (Configuration of Plasma Processing Apparatus)

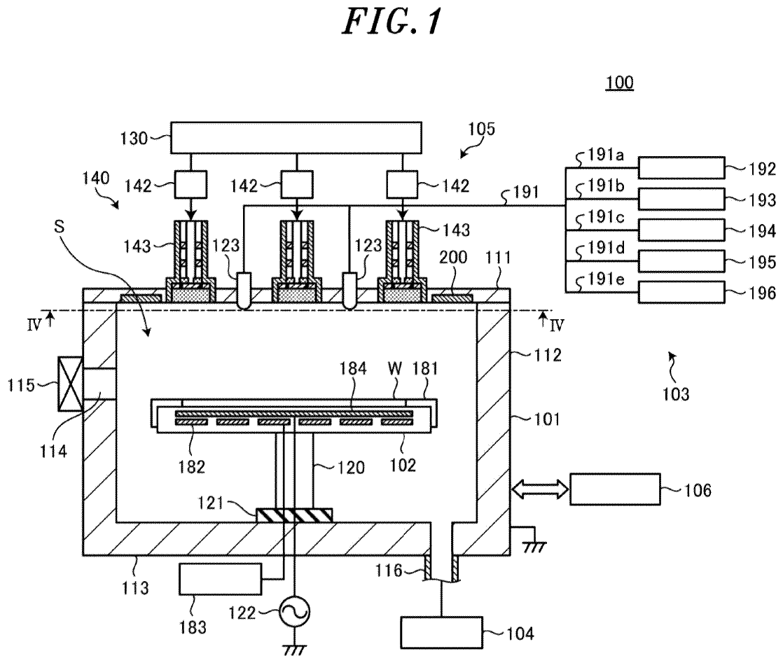

FIG. 1 is a schematic cross-sectional view showing an example of a configuration of a plasma processing apparatus according to the present embodiment. A plasma processing apparatus 100 shown in FIG. 1 includes a processing chamber 101, a placing table 102, a gas supply mechanism 103, an exhaust device 104, a microwave introducing device 105, and a controller 106. The processing chamber 101 accommodates a substrate W. The placing table 102 places the substrate W. The gas supply mechanism 103 supplies a gas into the processing chamber 101. The exhaust device 104 exhausts the inside of the processing chamber 101. The microwave introducing device 105 generates microwaves for generating plasma in the processing chamber 101, and introduces microwaves into the processing chamber 101. The controller 106 controls operations of individual components of the plasma processing apparatus 100.

The processing chamber 101 is made of a metal material such as aluminum or an alloy thereof, and provides a substantially cylindrical processing space S therein. The processing chamber 101 has a plate-shaped ceiling wall 111 and a plate-shaped bottom wall 113, and a sidewall 112 that connects them. The microwave introducing device 105 is provided at the upper portion of the processing chamber 101, and functions as a plasma generation device for generating plasma by introducing electromagnetic waves (microwaves) into the processing chamber 101. The microwave introducing device 105 will be described in detail later.

The ceiling wall 111 has a plurality of openings into which a microwave radiation mechanism, a resonator array structure, and a gas introducing part of the microwave introducing device 105, which will be described later, are fitted. The sidewall 112 is provided with a transfer port 114 for transferring the substrate W, which is a target object, between the processing chamber 101 and a transfer chamber (not shown) adjacent to the processing chamber 101. The transfer port 114 is opened and closed by a gate valve 115. The bottom wall 113 is provided with an exhaust device 104. The exhaust device 104 is provided at an exhaust line 116 connected to the bottom wall 113, and includes a vacuum pump and a pressure control valve. The inside of the processing chamber 101 is exhausted through the exhaust line 116 by the vacuum pump of the exhaust device 104. The pressure in the processing chamber 101 is controlled by a pressure control valve.

The placing table 102 is formed in a disc shape, and is made of ceramic such as AlN or the like. The placing table 102 is supported by a cylindrical support member 120 made of ceramic such as AlN that extending upward from the center of the bottom portion of the processing chamber 101. A guide ring 181 for guiding the substrate W is provided at the outer edge of the placing table 102. In addition, a lift pin (not shown) for lifting and lowering the substrate W is provided in the placing table 102 to be able to protrude from and retract below the upper surface of the placing table 102. Further, a resistance heating type heater 182 is embedded in the placing table 102, and heats the substrate W placed thereon through the placing table 102 by power supplied from a heater power supply 183. A thermocouple (not shown) is inserted into the placing table 102, and the heating temperature of the substrate W can be controlled to a predetermined temperature, e.g., within the range of 300° C. to 1000° C., based on a signal from the thermocouple. Further, an electrode 184 having substantially the same size as the substrate W is embedded above the heater 182 in the placing table 102, and a high-frequency bias power supply 122 is electrically connected to the electrode 184. The high-frequency bias power for attracting ions to the placing table 102 is applied to the electrode 184 from the high-frequency bias power supply 122. The high-frequency bias power supply 122 may not be provided depending on the characteristics of plasma processing.

The gas supply mechanism 103 includes a plurality of gas introducing nozzles 123 for introducing a plasma generating gas and a raw material gas for forming a desired film such as a carbon film or the like into the processing chamber 101. The gas introducing nozzles 123 are fitted into openings formed in the ceiling wall 111 of the processing chamber 101. A gas supply line 191 is connected to the gas introducing nozzle 123. The gas supply pipe 191 branches into five branch lines 191a, 191b, 191c, 191d, and 191e. The branch lines 191a, 191b, 191c, 191d, and 191e are connected to an Ar gas supply source 192, an O₂ gas supply source 193, an N₂ gas supply source 194, an H₂ gas supply source 195, and a C₂H₂ gas supply source 196. The Ar gas supply source 192 supplies Ar gas as a rare gas (noble gas) that is a plasma generating gas. The O₂ gas supply source 193 supplies O₂ gas as an oxidizing gas that is a cleaning gas. The N₂ gas supply source 194 supplies N₂ gas used as a purge gas or the like. The H₂ gas supply source 195 supplies H₂ gas as a reducing gas. The C₂H₂ gas supply source 196 supplies acetylene (C₂H₂) gas as a carbon-containing gas that is a film forming material gas. The C₂H₂ gas supply source 196 may supply another carbon-containing gas such as ethylene (C₂H₄).

Although not shown, the branch lines 191a, 191b, 191c, 191d, and 191e are provided with mass flow controllers for flow rate control and valves on both sides of the mass flow controllers. Further, a shower plate can be provided to supply C₂H₂ gas and H₂ gas to a position close to the substrate W to adjust the dissociation of the gas. The nozzles for supplying the gases can extend downward to obtain a similar effect.

As described above, the microwave introducing device 105 is provided above the processing chamber 101, and functions as a plasma generation device for generating plasma by introducing electromagnetic waves (microwaves) into the processing chamber 101.

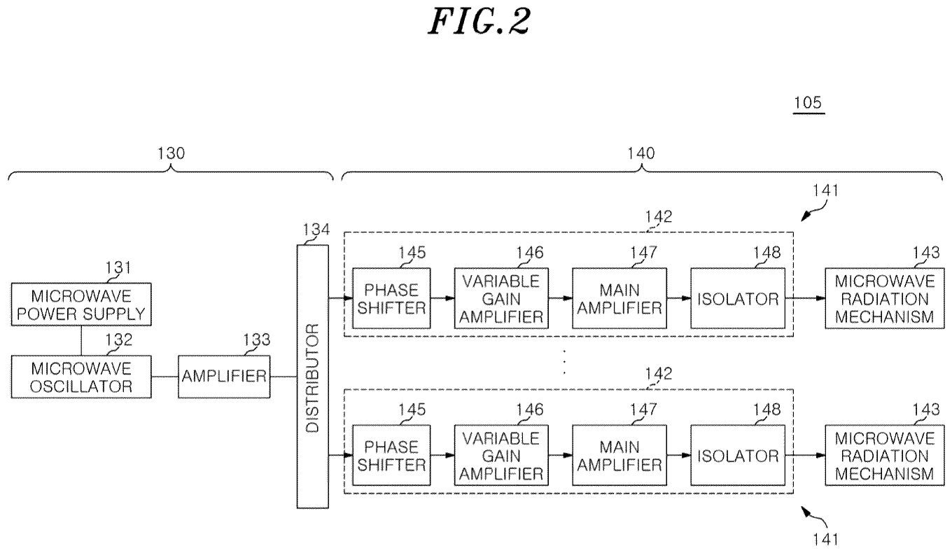

FIG. 2 is a diagram showing an example of the configuration of the microwave introducing device according to the present embodiment. As shown in FIGS. 1 and 2, the microwave introducing device 105 has the ceiling wall 111 of the processing chamber 101, a microwave output part 130, and an antenna unit 140. The ceiling wall 111 functions as a ceiling plate. The microwave output part 130 generates microwaves and outputs microwaves by distributing them to a plurality of paths. The antenna unit 140 introduces the microwaves outputted from the microwave output part 130 into the processing chamber 101.

The microwave output part 130 has a microwave power supply 131, a microwave oscillator 132, an amplifier 133, and a distributor 134. The microwave oscillator 132 is a solid state oscillator, and oscillates microwaves (for example, performs PLL oscillation) at 2.45 GHz, for example. The microwave frequency is not limited to 2.45 GHz, and may be within the range of 700 MHz to 10 GHz, such as 915 MHz, 8.35 GHz, 5.8 GHz, and 1.98 GHz. The amplifier 133 amplifies the microwaves oscillated by the microwave oscillator 132. The distributor 134 distributes the microwaves amplified by the amplifier 133 to a plurality of paths. The distributor 134 distributes the microwaves while matching impedances on the input side and the output side.

The microwave output part 130 can adjust the frequency, the power, and the bandwidth of the microwave. The microwave output part 130 can generate single-frequency microwaves by setting the bandwidth of the microwaves to approximately 0, for example. The microwave output part 130 can generate microwaves containing a plurality of frequency components belonging to a predetermined frequency bandwidth (hereinafter, appropriately referred to as “broadband microwaves”). The plurality of frequency components may have the same power, or only the central frequency component within the band may have a power greater than the power of the other frequency components. The microwave output part 130 can adjust the power of the microwaves within a range of 0 W to 5000 W, for example. The microwave output part 130 can adjust the frequency of the microwaves or the central frequency of the broadband microwaves within a range of 2.3 GHz to 2.5 GHz, for example, and can adjust the bandwidth of the broadband microwaves within a range of 0 MHz to 100 MHz, for example. Further, the microwave output part 130 can adjust the frequency pitch (carrier pitch) of the plurality of frequency components of the broadband microwaves within a range of 0 kHz to 25 kHz, for example. The microwave output part 130 is an example of a microwave generator.

The antenna unit 140 includes a plurality of antenna modules 141. Each of the plurality of antenna modules 141 introduces the microwaves distributed by the distributor 134 into the processing chamber 101. The plurality of antenna modules 141 have the same configuration. Each antenna module 141 has an amplifier part 142 that mainly amplifies and outputs the distributed microwaves, and a microwave radiation mechanism 143 that radiates the microwaves outputted from the amplifier part 142 into the processing chamber 101.

The amplifier part 142 includes a phase shifter 145, a variable gain amplifier 146, a main amplifier 147, and an isolator 148. The phase shifter 145 shifts the phase of the microwaves. The variable gain amplifier 146 controls the power level of the microwaves inputted to the main amplifier 147. The main amplifier 147 is configured as a solid-state amplifier. The isolator 148 separates the reflected microwaves reflected by an antenna part of the microwave radiation mechanism 143, which will be described later, and directed toward the main amplifier 147.

Here, the microwave radiation mechanism 143 will be described with reference to FIG. 3. FIG. 3 is a diagram showing an example of a microwave radiation mechanism according to the present embodiment. As shown in FIG. 1, a plurality of microwave radiation mechanisms 143 are provided at the ceiling wall 111. As shown in FIG. 3, the microwave radiation mechanism 143 has a cylindrical outer conductor 152 and an inner conductor 153 provided coaxially with the outer conductor 152 within the outer conductor 152. The microwave radiation mechanism 143 has a coaxial tube 151 having a microwave transmission line between the outer conductor 152 and the inner conductor 153, a tuner 154, a power supply part 155, and an antenna part 156. The tuner 154 matches the impedance of the load to the characteristic impedance of the microwave power supply 131. The power supply part 155 supplies the amplified microwaves from the amplifier part 142 to the microwave transmission line. The antenna part 156 radiates the microwaves from the coaxial tube 151 into the processing chamber 101. The microwave radiation mechanism 143 is an example of a microwave radiator.

The microwaves amplified by the amplifier part 142 are introduced into the power supply part 155 from the side surface of the upper end of the outer conductor 152 via a coaxial cable, and the power supply part 155 radiates the microwaves via a power supply antenna, for example. By radiating the microwaves, the microwave power is supplied to the microwave transmission line between the outer conductor 152 and the inner conductor 153, and the microwave power propagates toward the antenna part 156.

The antenna part 156 is provided at the lower end of the coaxial tube 151. The antenna part 156 has a disc-shaped planar antenna 161 connected to the lower end of the inner conductor 153, a wave retardation member 162 located on the upper surface side of the planar antenna 161, and a microwave transmitting plate 163 located on the bottom surface side of the planar antenna 161. The microwave transmitting plate 163 is an example of a microwave transmitting window. The microwave transmitting plate 163 is fitted into the ceiling wall 111, and the bottom surface thereof is exposed to the inner space of the processing chamber 101. The planar antenna 161 has a slot 161a formed to penetrate therethrough. The shape of the slot 161a is appropriately set such that the microwaves are efficiently radiated. A dielectric may be inserted into the slot 161a.

The wave retardation member 162 is made of a material having a dielectric constant greater than that of a vacuum. The phase of the microwaves can be adjusted depending on the thickness of the wave retardation member 162 to maximize the radiation energy of the microwaves. The microwave transmitting plate 163 is also formed of a dielectric and has a shape that allows the microwaves to be radiated efficiently in a TE mode. Further, the microwaves that have transmitted the microwave transmitting plate 163 generate plasma in the inner space of the chamber 101. The wave retardation member 162 and the microwave transmitting plate 163 may be made of, e.g., quartz, ceramic, fluorine-based resin such as polytetrafluoroethylene resin, polyimide-based resin, or the like.

The tuner 154 constitutes a slug tuner. As shown in FIG. 3, the tuner 154 includes slugs 171a and 171b, an actuator 172, and a tuner controller 173. The slugs 171a and 171b are two slugs that are located at the base end side (upper end side) of the antenna part 156 of the coaxial tube 151. The actuator 172 drives the two slugs individually. The tuner controller 173 controls the actuator 172.

The slugs 171a and 171b are formed in an annular plate shape and made of a dielectric material such as ceramic or the like. The slugs 171a and 171b are located between the outer conductor 152 and the inner conductor 153 of the coaxial tube 151. The actuator 172 individually drives the slugs 171a and 171b by rotating two screws that are provided in the inner conductor 153 to be screw-coupled to the slugs 171a and 171b. Then, the actuator 172 moves the slugs 171a and 171b in a vertical direction based on a command from the tuner controller 173. The tuner controller 173 adjusts the positions of the slugs 171a and 171b such that an impedance of an end portion becomes 50 Ω.

The main amplifier 147, the tuner 154, and the planar antenna 161 are located close to each other. The tuner 154 and the planar antenna 161 form a lumped constant circuit and function as a resonator. Although there exists impedance mismatch at the installation portion of the planar antenna 161, the impedance is directly tuned with respect to the plasma load by the tuner 154, so that the impedance can be tuned with high precision by including plasma and the influence of the reflection on the planar antenna 161 can be eliminated.

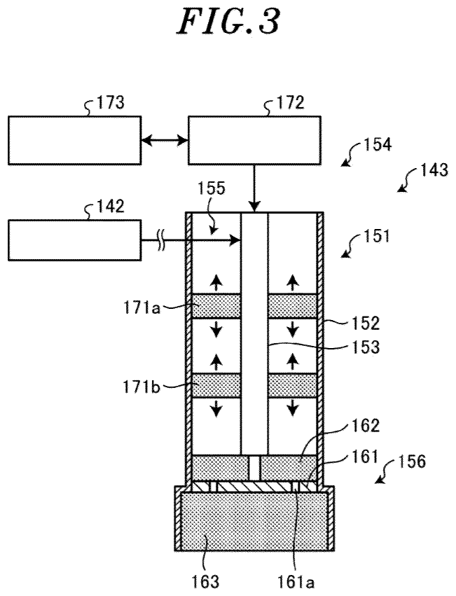

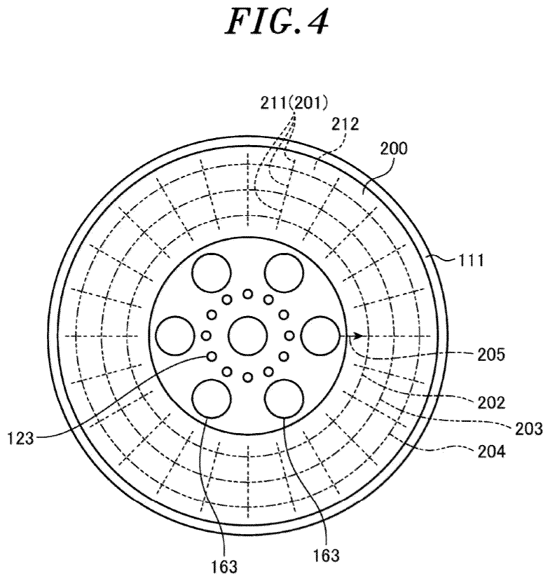

FIG. 4 is a plan view showing an example of a ceiling wall of a processing chamber according to the present embodiment. FIG. 4 shows the IV-IV cross section of FIG. 1 that corresponds to the processing space S located inner than the sidewall 112. As shown in FIG. 4, in the present embodiment, seven microwave radiation mechanisms 143 are provided, and the microwave transmitting plates 163 corresponding thereto are arranged uniformly in a hexagonal close-packed manner. In other words, one of the seven microwave transmitting plates 163 is located at the center of the ceiling wall 111, and the other six microwave transmitting plates 163 are arranged around the central microwave transmitting plate 163. The seven microwave transmitting plates 163 are arranged such that the adjacent microwave transmitting plates 163 are spaced apart from each other at an equal interval. Further, the plurality of gas introducing nozzles 123 of the gas supply mechanism 103 are arranged to surround the periphery of the central microwave transmitting plate 163. The number of microwave radiation mechanisms 143 is not limited to seven.

A resonator array structure 200 is provided around the microwave transmitting plate 163. In other words, the resonator array structure 200 is provided in the ceiling wall 111 to be located between the microwave transmitting plate 163 (microwave transmitting window) and the connection portion between the ceiling wall 111 and the sidewall 112. In other words, the resonator array structure 200 is provided in the ceiling wall 111 to surround the plurality of microwave radiation mechanisms 143 (microwave radiators) and the plurality of microwave transmitting plates 163 (microwave transmitting windows). The resonator array structure 200 is formed by arranging a plurality of resonators that can resonate with the magnetic field component of the microwaves and have sizes smaller than the wavelength of the microwaves. The resonator array structure 200 is located in the ceiling wall 111, for example. In other words, the resonator array structure 200 is fitted into a recess formed in the ceiling wall 111, for example, and the bottom surface of the ceiling wall 111 and the bottom surface of the resonator array structure 200 form the same plane.

By locating the resonator array structure 200 in the ceiling wall 111 to surround the microwave transmitting plates 163, the propagation of the surface waves that propagate through the plasma interface among the microwaves supplied to the processing space S by the microwave radiation mechanisms 143 is suppressed. The electromagnetic waves propagate mainly in the sheath, and the propagation mode thereof is affected by both the ceiling wall 111 and the plasma adjacent thereto. By appropriately setting the magnetic permeability of the resonator array structure 200, it is possible to obtain a state in which the propagation mode of the electromagnetic waves propagating through the sheath does not exist. In other words, in the present embodiment, the propagation of the electromagnetic waves can be suppressed without directly installing a metal body in the propagation path of the electromagnetic waves.

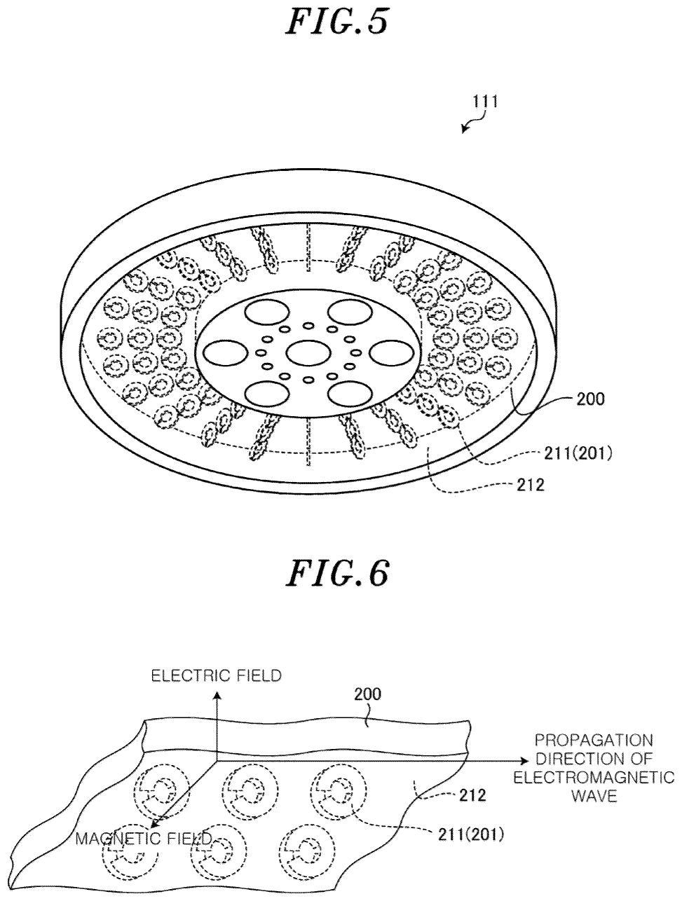

Here, the specific configuration of the resonator array structure 200 will be described with reference to FIGS. 4 to 6. FIG. 5 is a perspective view showing an example of the ceiling wall of the processing chamber according to the present embodiment. As shown in FIGS. 4 and 5, the resonator array structure 200 has an annular ring shape surrounding the microwave transmitting plates 163, and the plurality of resonators 201 are arranged in the circumferential direction and the radial direction. Each resonator 201 includes a C-shaped ring member 211 made of a conductor and a dielectric 212 surrounding the periphery of the ring member 211. In other words, each resonator 201 may include a dielectric 212 surrounding the periphery of the ring member 211. For example, the dielectric forming the resonator array structure 200 also serves as the dielectric 212. In FIGS. 4 and 5, the arrangement of the ring members 211 in the plurality of resonators 201 is shown. The ring members 211 are arranged in a direction in which a C shape is visible in the cross-sectional direction of the resonator array structure 200 in FIG. 1. Further, each resonator 201 may include two or more C-shaped ring members 211 made of a conductor. In this case, even if the size of the ring member 211 is small, it is possible to deal with a low frequency.

The plurality of resonators 201 of the resonator array structure 200 are radially arranged from the center of the ceiling wall 111 of the processing chamber 101. Further, the plurality of resonators 201 are arranged on a plurality of circumferences 202 to 204 that are concentric circles. In other words, the plurality of resonators 201 are arranged in a direction in which the holes of the ring members 211 intersect with the circumferences 202 to 204. Further, a plurality of resonator array structures 200 may be arranged in the ceiling wall 111 to surround the plurality of microwave radiation mechanisms 143 (microwave radiators) and the plurality of microwave transmitting plates 163 (microwave transmitting windows). In this case, in each resonator array structure 200, the plurality of resonators 201 are arranged radially from the center of the microwave transmitting plate 163. In other words, the plurality of resonator array structures 200 are arranged to surround each of the seven microwave transmitting plates 163. In other words, the plurality of resonator array structures 200 are arranged in the ceiling wall 111 to surround each of the plurality of microwave transmitting plates 163 (microwave transmitting windows).

FIG. 6 is a diagram showing an example of the relationship between the traveling direction of the electromagnetic waves and the direction of the ring member according to the present embodiment. FIG. 6 shows the traveling direction of the electromagnetic waves in a part of the resonator array structure 200 and the orientation of the ring members 211. Further, the ring members 211 are surrounded by the dielectric 212. In the present embodiment, among the microwaves supplied from the microwave radiation mechanisms 143, the surface waves propagating along the plasma interface propagate radially from the center of the ceiling wall 111 as indicated by arrows 205 indicating the direction of propagation of the electromagnetic waves in FIG. 4. In other words, since the electromagnetic waves in the sheath propagate in the TM mode, the magnetic field is directed horizontally with respect to the traveling direction of the electromagnetic waves. In the resonator array structure 200, the plurality of resonators 201 are arranged such that the magnetic field penetrates through the ring members 211.

Here, an example of a configuration of each of the plurality of resonators 201 will be described. For example, shown in FIGS. 4 and 5, the plurality of resonators 201 may be configured by embedding the plurality of ring members 211 in the dielectric 212 constituting the resonator array structure 200. Each of the plurality of resonators 201 constitutes a series resonant circuit including a capacitor equivalent element and a coil equivalent element. Further, each of the plurality of resonators 201 has a size less than 1/10 of the wavelength of the microwaves.

Further, in the resonator 201, the ring member 211 may be formed on the surface of a dielectric plate, as shown in FIGS. 7 to 10. In this case, the series resonant circuit is realized by patterning a conductor on the plane. FIG. 7 is a diagram showing an example of a configuration of a resonator according to the present embodiment. A resonator 201A shown in FIG. 7 has a structure in which two C-shaped concentric ring members 211A made of a conductor and arranged in opposite directions are laminated on one surface of a dielectric plate 212A. Capacitor equivalent elements are formed on the opposing surfaces of the inner ring member 211A and the outer ring member 211A and on both ends of each ring member 211A, and coil equivalent elements are formed along the ring members 211A. Accordingly, the resonator 201A can constitute a series resonant circuit.

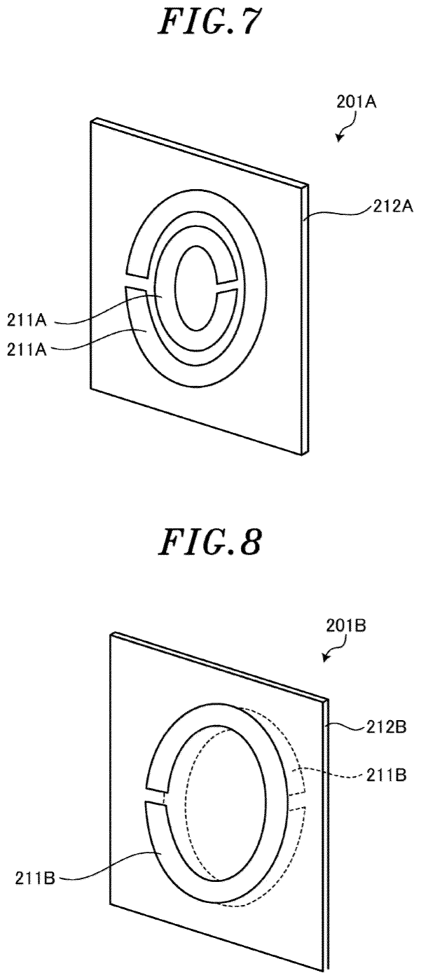

FIG. 8 is a diagram showing an example of a configuration of a resonator according to the present embodiment. A resonator 201B shown in FIG. 8 has a structure in which a dielectric plate 212B is located between two C-shaped ring members 211B made of a conductor and arranged adjacent to each other in opposite directions. In other words, in the resonator 201B, the dielectric plate 212B is embedded between the two C-shaped ring members 211B arranged in the opposite directions. Capacitor equivalent elements are formed on the opposing surfaces of the two C-shaped ring members 211B and on both ends of each ring member 211B, and coil equivalent elements are formed along the ring members 211B. Accordingly, the resonator 201B can constitute a series resonant circuit. Further, the resonator 201B can be formed for each set of two C-shaped ring members 211B.

In the resonator 201B shown in FIG. 8, the arrangement number (hereinafter, also referred to as “laminated number”) of ring members 211B is two, but the laminated number of the ring members 211B may be greater than two. FIG. 9 is a diagram showing another example of the configuration of the resonator according to the present embodiment. The resonator 201B shown in FIG. 9 has a structure in which the dielectric plate 212B is located between the N (N≥2) C-shaped ring members 211B made of a conductor and arranged adjacent to each other in the opposite directions. With such a structure, the resonator 201B can constitute a series resonant circuit.

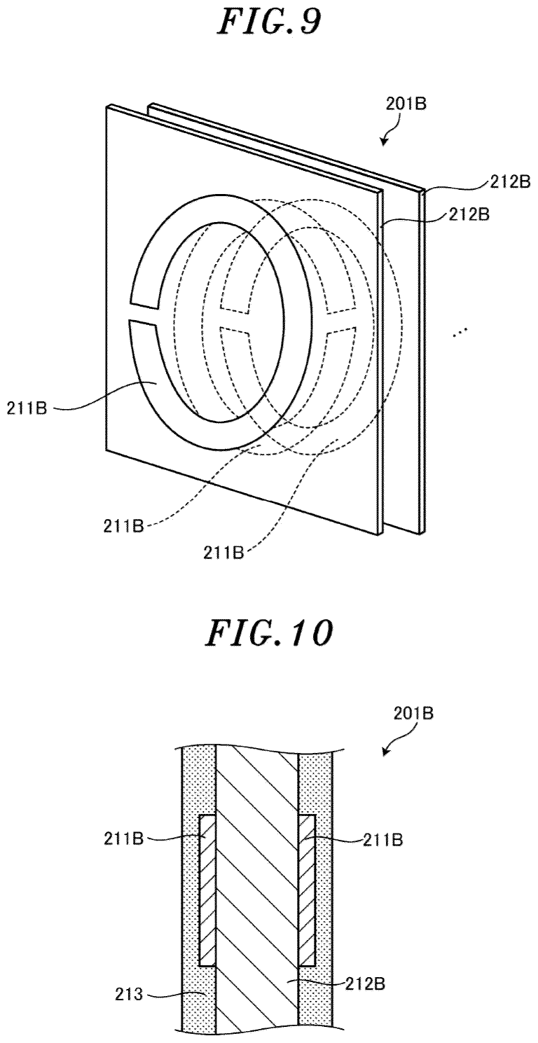

Further, an insulating coating film may be formed on each of the plurality of resonators 201. FIG. 10 is a diagram showing an example of a cross section of a resonator according to the present embodiment. FIG. 10 shows a side cross section of the resonator 201B shown in FIG. 8. An insulating coating film (an example of a dielectric film) 213 is formed on the surface of the resonator 201B. The material of the coating film 213 is ceramic, for example. The thickness of the coating film 213 is within a range of 0.001 mm to 2 mm, for example. By forming the insulating coating film 213 on each of the plurality of resonators 201, abnormal discharge in each of the plurality of resonators 201 can be suppressed. Further, by forming the insulating coating film 213 on each of the plurality of resonators 201, exposure of the ring members 211B to plasma can be suppressed.

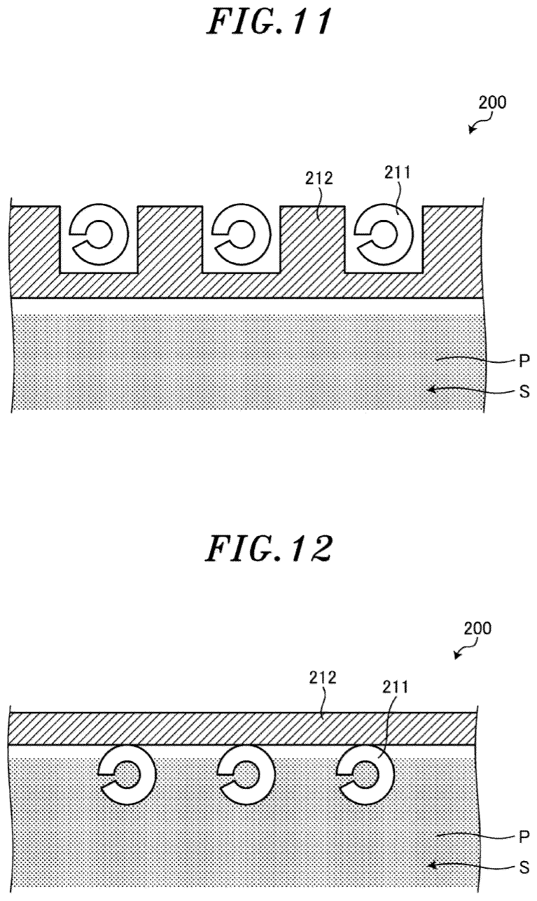

Further, the plurality of resonators 201 may be configured such that the plurality of ring members 211 can be inserted from the atmospheric side of the resonator array structure 200. FIG. 11 is a diagram showing an example of the arrangement of the resonators in the resonator array structure according to the present embodiment. In the resonator array structure 200 shown in FIG. 11, the ring members 211 can be fitted into grooves or the like formed in the dielectric 212 from the atmospheric side, and the ring members 211 are not exposed to the plasma P generated in the processing space S. In addition, the ring members 211 can be replaced without opening the processing chamber 101 to the atmosphere. The ring member 211 can be replaced with the ring member 211 having a different resonance frequency, for example.

Further, the plurality of resonators 201 may be arranged to be exposed to the processing space S side of the resonator array structure 200. FIG. 12 is a diagram showing an example of the arrangement of the resonators in the resonator array structure according to the present embodiment. In the resonator array structure 200 shown in FIG. 12, the ring members 211 are exposed to the processing space S side from the dielectric 212, and the ring members 211 are exposed to the plasma P produced in the processing space S. In this case, the ring members 211 may be coated with an insulator such as the insulating coating film 213 described above, or the conductors of the ring members 211 may be exposed. If it is required to suppress particle generation, it is preferable that the ring members 211 are coated with an insulator.

The controller 106 has a processor, a memory, and an input/output interface. The memory stores programs, process recipes, and the like. The processor reads out and executes the programs from the memory, and controls individual components of the plasma processing apparatus 100 via the input/output interface based on the process recipes stored in the memory.

The controller 106 performs control, in the case of producing plasma in the processing space S, such that the microwaves supplied to the processing space S by the microwave radiation mechanisms 143 resonate with the plurality of resonators 201 in a target frequency band higher than the resonant frequency of the plurality of resonators 201. Here, the resonant frequency is, e.g., a frequency at which the transmission characteristic value (e.g., S₂₁ value) of the plurality of resonators 201 becomes a minimum value.

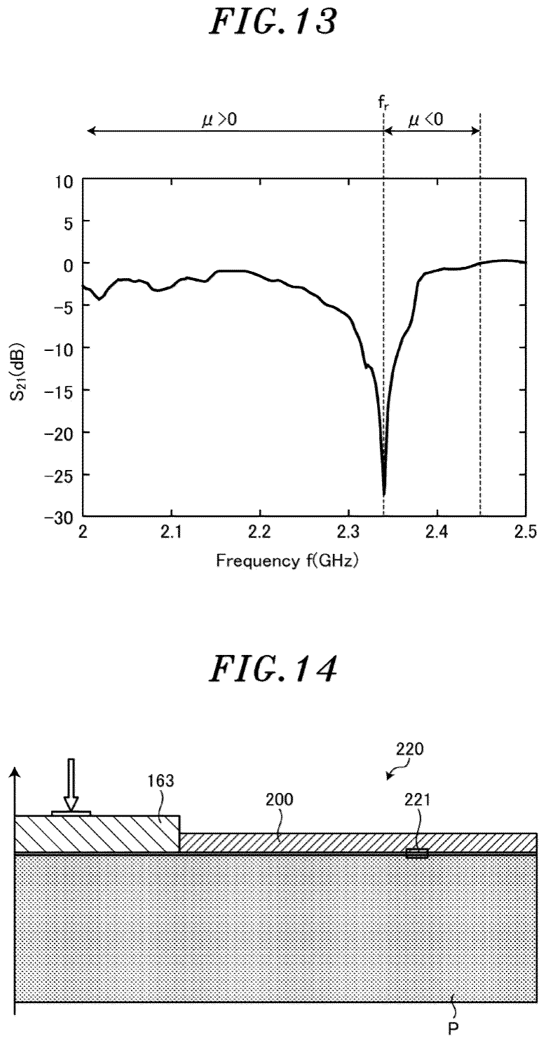

FIG. 13 is a diagram showing an example of the relationship between the S₂₁ value of the resonator and the frequency of the microwaves. When the frequency of the microwaves supplied to the processing space S by the microwave radiation mechanisms 143 coincides with the resonant frequency fᵣ (=about 2.35 GHz) of the plurality of resonators 201, the S₂₁ value of the plurality of resonators 201 becomes a minimum value, and the resonance occurs between the microwaves and the plurality of resonators 201. The resonance between the microwaves and the plurality of resonators 201 is maintained even in a predetermined frequency band (e.g., about 0.1 GHz) higher than the resonant frequencies fᵣ of the plurality of resonators 201. In a predetermined frequency band higher than the resonant frequencies fᵣ of the plurality of resonators 201, the propagation mode of the surface waves in the sheath of the processing space S can be eliminated by the resonance between the microwaves and the plurality of resonators 201. The target frequency band in the present embodiment is set to a predetermined frequency band (for example, about 0.1 GHz) higher than the resonance frequencies fᵣ of the plurality of resonators 201. For example, the target frequency band is preferably within 0.05 times the resonance frequencies fᵣ of the plurality of resonators 201. The resonance frequencies fᵣ of the plurality of resonators 201 arranged on the plurality of circumferences 202 to 204 are the same, for example.

Regarding the propagation of the electromagnetic waves to the plurality of resonators, the relationship of the resonance frequency, the refractive index, the dielectric constant, and the magnetic permeability is reported in “Electromagnetic parameter retrieval from inhomogeneous metamaterials” of “PHYSICAL REVIEW E 71,036 617 (2005)” by D. R. Smith, D. C. Vier, Th. Koschny and C. M. Soukoulis, for example.

### [Simulation Model]

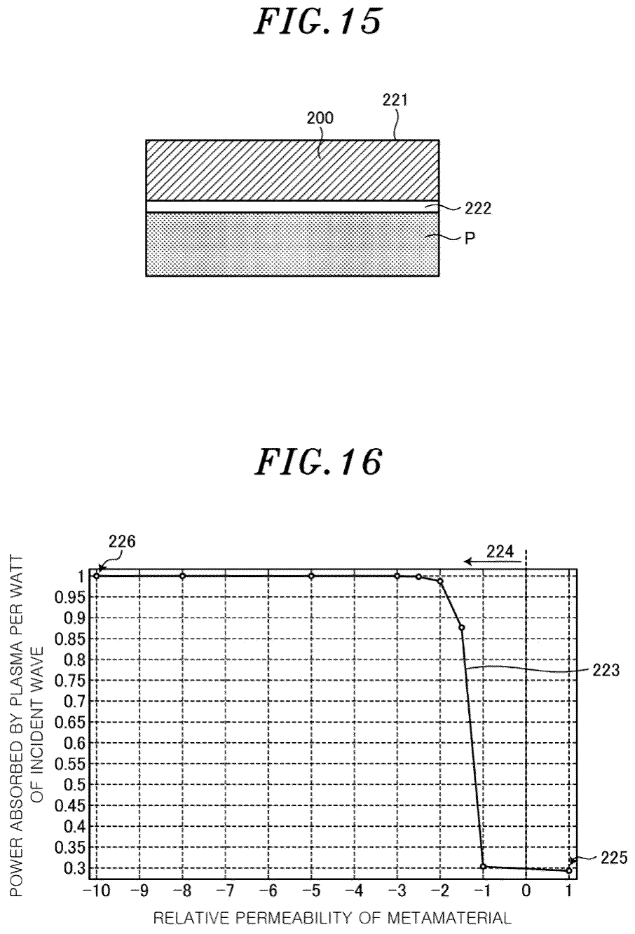

Next, a simulation model in which the resonator array structure 200 is located in the ceiling wall 111 will be described. FIG. 14 is a diagram showing an example of the simulation model. FIG. 15 is an enlarged view showing an example of the vicinity of the sheath of the simulation model. The simulation model 220 shown in FIG. 14 is an axially symmetric model in the case of providing one antenna module 141 at the center of the ceiling wall 111 and supplying the electromagnetic waves in the ultra high frequency (UHF) band. The resonator array structure 200 can be applied to both cases in which the antenna unit 140 is a multi-antenna including the plurality of antenna modules 141 and in which the antenna unit 140 is a single antenna including one antenna module 141. Hence, a single antenna is used in the simulation model 220. In the case of a single antenna, one antenna module 141 corresponds to a microwave source that radiates microwaves using one planar slot antenna. The plasma P is generated by the electromagnetic waves supplied from the microwave transmitting plates 163 of the antenna module 141. The dielectric constant ϵᵣ of the plasma P is set as ϵᵣ=−100−5i, for example.

As shown in FIG. 15, when a region 221 near the boundary between the resonator array structure 200 and the plasma P is enlarged, a sheath 222 is set at the boundary between the resonator array structure 200 and the plasma P. The sheath 222 is vacuum, and is set such that the electromagnetic waves can propagate when the resonators 201 of the resonator array structure 200 are not resonating.

### [Simulation Results]

Next, the simulation results will be described with reference to FIGS. 16 to 18. FIG. 16 is a graph showing an example of the relationship between the relative permeability of the resonator array structure and the power absorbed by the plasma. A graph 223 shown in FIG. 16 represents the power absorbed by the plasma P per 1 W of incident wave in the case of setting the relative permeability of the resonator array structure 200 (metamaterial) from “1” to “−10”. The relative permittivity of the resonator array 200 is set to “9.6”. When the relative permeability of the resonator array 200 is “1” (point 225 in FIG. 16), about 0.3 W is absorbed by the plasma P per 1 W of incident wave, and about 0.7 W of the energy is dissipated as the surface waves.

Next, a metamaterial region 224 where the relative permittivity of the resonator array 200 becomes negative will be described. When the relative permeability of the resonator array 200 is “−1”, about 0.3 W is absorbed by the plasma P per 1 W of incident wave, and about 0.7 W of the energy is dissipated as the surface waves. When the relative permeability of the resonator array structure 200 is “−1.5”, about 0.875 W is absorbed by the plasma P per 1 W of incident wave, and about 0.125 W of the energy is dissipated as the surface waves. When the relative permeability of the resonator array structure 200 is “−2”, about 0.98 W is absorbed by the plasma P per 1 W of incident wave, and about 0.02 W of the energy is dissipated as the surface waves. In the region where the relative permeability of the resonator array structure 200 is within a range of “−2.5” to “−10” (point 226 in FIG. 16), 1 W is absorbed by the plasma P per 1 W of incident wave, and the energy is hardly dissipated as the surface waves. In other words, in the metamaterial region 224, when the relative permeability of the resonator array structure 200 is “−2” or less, it is possible to suppress the propagation of the surface waves.

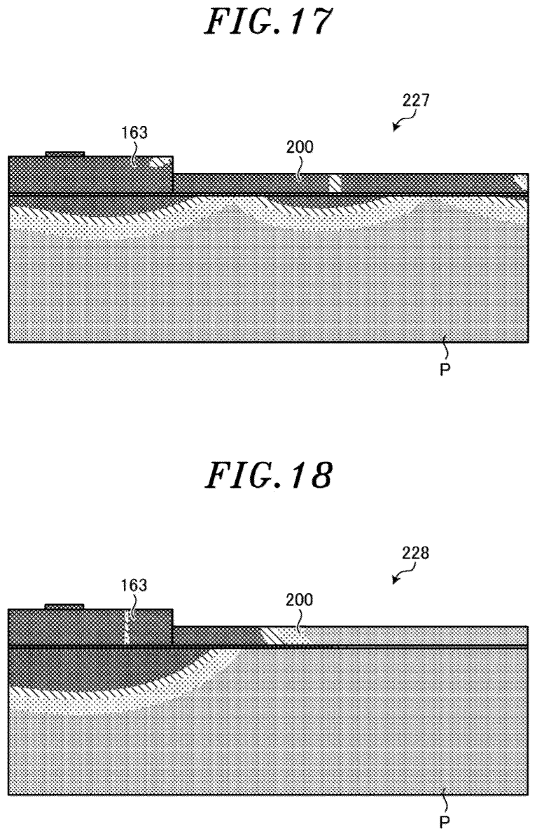

FIG. 17 is a diagram showing an example of a simulation result in the case where the relative permeability of the resonator array structure is a positive value. A simulation result 227 shown in FIG. 17 represents the electric field intensity in the case where the relative permeability of the resonator array structure 200 is “1” (point 225 in FIG. 16). According to the simulation result 227, the electromagnetic waves (surface waves) supplied from the microwave transmitting plates 163 propagate along the surface of the resonator array structure 200 toward the sidewall 112. In other words, according to the simulation result 227, the electromagnetic waves (surface waves) supplied from the microwave transmitting plates 163 propagate through the sheath 222 and reach the sidewall 112.

FIG. 18 is a diagram showing an example of the simulation result in the case where the relative permeability of the resonator array structure is a negative value. A simulation result 228 shown in FIG. 18 represents the electric field intensity in the case where the relative permeability of the resonator array structure 200 is “−10” (point 226 in FIG. 16). According to the simulation result 228, in the resonator array structure 200, the propagation of the electromagnetic waves (surface waves) supplied from the microwave transmitting plates 163 is suppressed. In other words, according to the simulation result 228, the resonator array structure 200 can suppress the propagation of the surface waves, and suppress the propagation of the electromagnetic waves through the gap such as the connection portion between the ceiling wall 111 and the sidewall 112.

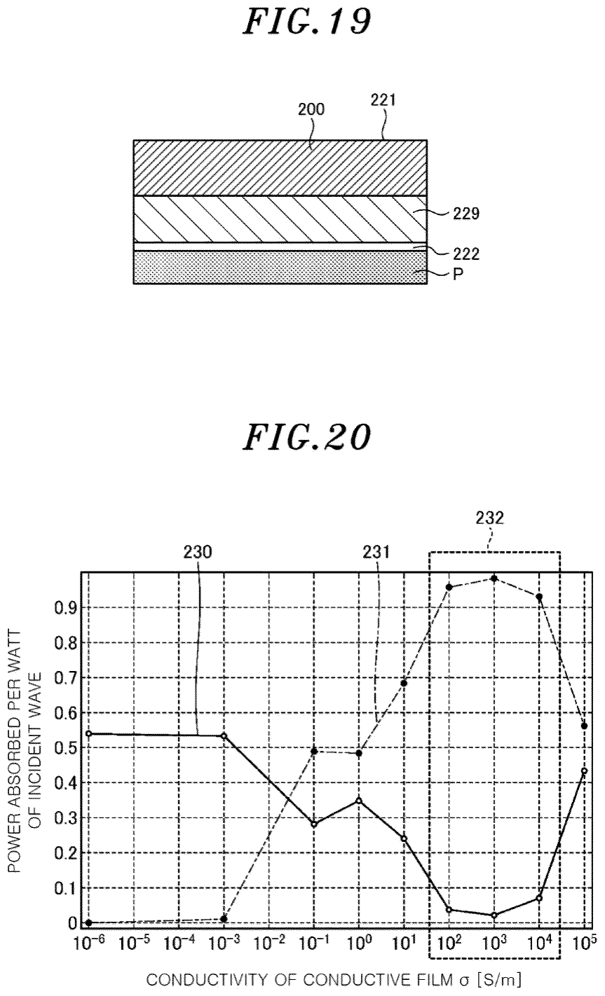

Next, a simulation result obtained when a conductive film is formed in the inner wall of the processing chamber 101, i.e., when a conductive film exists on the surface of the ceiling wall 111 including the resonator array structure 200 on the processing space S side will be described with reference to FIGS. 19 to 23. FIG. 19 is an enlarged view showing an example of the vicinity of the sheath in a simulation model in the case where a conductive film exists. In FIG. 19, the region 221 near the boundary between the resonator array structure 200 and the plasma P in the case where a conductive film exists is enlarged. In FIG. 19, a conductive film 229 is set on the bottom surface of the resonator array structure 200, and the sheath 222 is set at the boundary between the conductive film 229 and the plasma P. The sheath 222 is vacuum, and is set such that the electromagnetic waves can propagate when the resonators 201 of the resonator array structure 200 are not resonating. The conductive film 229 may be, e.g., aluminum fluoride (AlF₃). Further, the conductive film 229 may be by-products generated during the process.

FIG. 20 is a graph showing an example of the relationship between the conductivity of the conductive film and the power absorbed by the plasma and the conductive film. FIG. 20 shows the conductivity σ [S/m] of the conductive film 229 and the power absorbed by the plasma P and the conductive film 229. Further, in FIG. 20, the relative permeability of the resonator array structure 200 (metamaterial) is set to “1” and the relative permittivity is set to “9.6”. A graph 230 shows the power absorbed by the plasma P per 1 W of incident wave. A graph 231 shows the power absorbed by the conductive film 229 per 1 W of incident wave.

From the graph 231, when the conductive film 229 has a specific conductivity σ as shown in a region 232, the heat loss in the conductive film 229 increases considerably. For example, when the conductivity σ is 10³ [S/m], about 0.98 W is absorbed by the conductive film 229 per 1 W of incident wave, and about 0.02 W is absorbed by the plasma P per 1 W of incident wave. In other words, most of the incident waves are absorbed by the conductive film 229, which results in heat loss. When the conductivity σ of the conductive film 229 is 10⁵ [S/m] and 10 [S/m] or less, the incident waves are not absorbed by the conductive film 229 compared to that in the region 232.

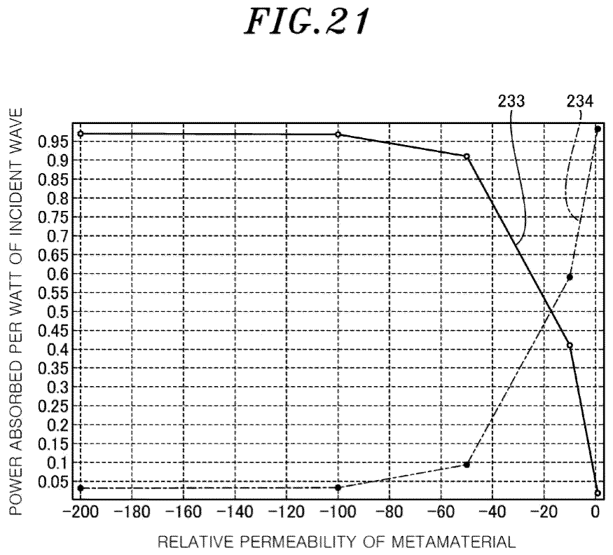

FIG. 21 is a graph showing an example of the relationship between the relative permeability of the resonator array structure and the power absorbed by the plasma and the conductive film. FIG. 21 shows the power absorbed by the plasma P and the conductive film 229 in the case of setting the conductivity σ of the conductive film 229 as σ=10³ [S/m] and changing the relative permeability of the resonator array structure 200 (metamaterial) from “1” to “−200”. A graph 233 shows the power absorbed by the plasma P per 1 W of incident wave. A graph 234 shows the power absorbed by the conductive film 229 per 1 W of incident wave. The relative permittivity of the resonator array structure 200 is set to “9.6”. When the relative permeability of the resonator array structure 200 is “1”, about 0.02 W is absorbed by the plasma P per 1 W of incident wave, and about 0.98 W is absorbed by the conductive film 229 per 1 W of incident wave. In this case, the heat loss in the conductive film 229 increases considerably. In other words, heat is generated due to energy loss in the conductive film 229, so that the energy efficiency decreases and particles are easily generated.

If the relative permeability of the resonator array structure 200 is changed to a large negative value, when the relative permittivity is “−50”, about 0.91 W is absorbed by the plasma P per 1 W of incident wave, and about 0.09 W is absorbed by the conductive film 229 per 1 W of incident wave. When the relative permeability of the resonator array structure 200 is “−100”, about 0.97 W is absorbed by the plasma P per 1 W of incident wave, and about 0.03 W is absorbed by the conductive film 229 per 1 W of incident wave. When the relative permeability of the resonator array 200 is “−200”, about 0.97 W is absorbed by the plasma P per 1 W of incident wave, and about 0.03 W is absorbed by the conductive film 229 per 1 W of incident wave, similarly to when the relative permeability of the resonator array 200 is “−100”. In other words, in the region where the relative permeability of the resonator array 200 is “−100” or less, it is possible to substantially completely suppress the heat loss in the conductive film 229.

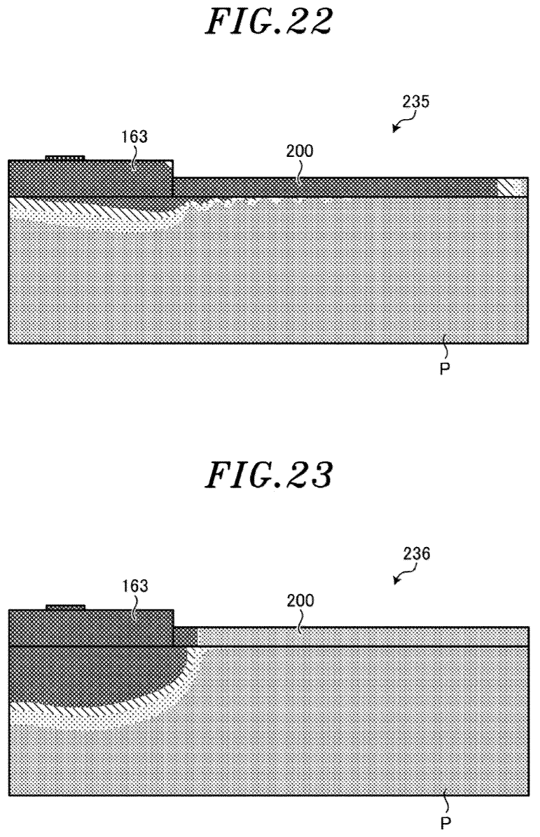

FIG. 22 is a diagram showing an example of the simulation result obtained when a conductive film exists and the relative permeability of the resonator array is a positive value. The simulation result 235 shown in FIG. 22 represents the electric field intensity in the case where the conductive film 229 shown in FIG. 19 exists and the relative permeability of the resonator array 200 is “1”. According to the simulation result 235, the electromagnetic waves (surface waves) supplied from the microwave transmitting plates 163 propagate along the surface of the resonator array structure 200 toward the sidewall 112 while being absorbed by the conductive film 229. In other words, according to the simulation result 235, the electromagnetic waves (surface waves) supplied from the microwave transmitting plates 163 propagate through the sheath 222 and reach the sidewall 112 while being absorbed by the conductive film 229.

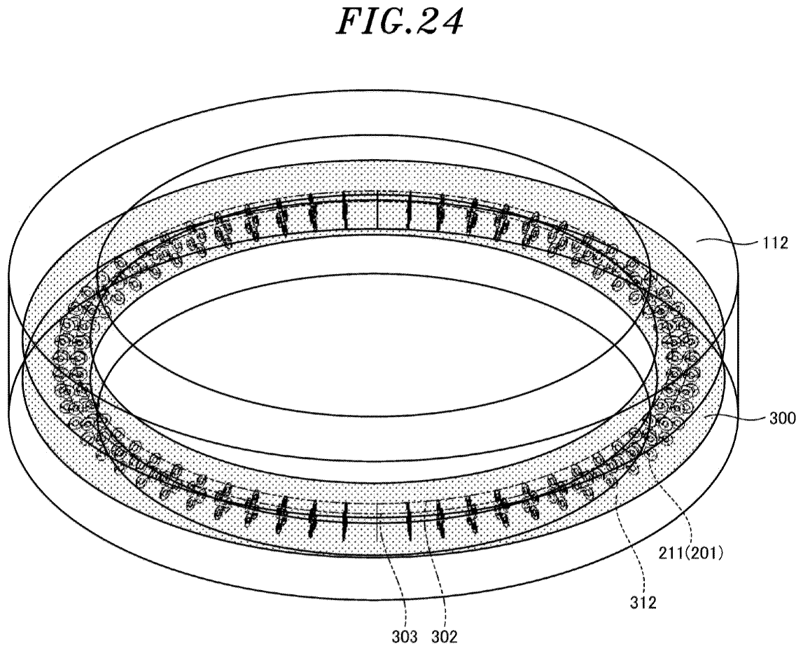

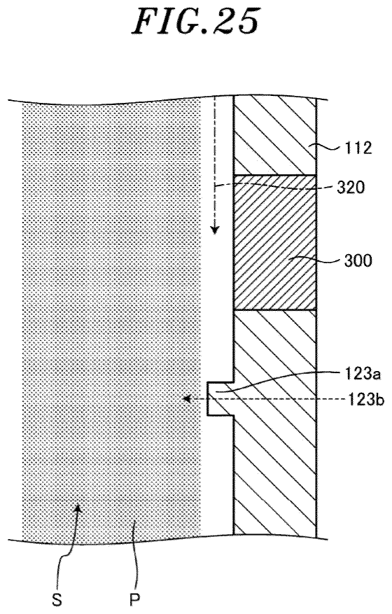

FIG. 23 is a diagram showing an example of the simulation result obtained when a conductive film exists and the relative permeability of the resonator array structure is a negative value. The simulation result 236 shown in FIG. 23 represents the electric field intensity in the case where the conductive film 229 shown in FIG. 19 exists and the relative permeability of the resonator array structure 200 is “−100”. According to the simulation result 236, the electromagnetic waves (surface waves) supplied from the microwave transmitting plates 163 are mostly absorbed by the plasma P without being absorbed by the conductive film 229. In other words, according to the simulation result 236, the resonator array 200 can suppress the propagation of the surface waves and the absorption of the surface waves in the conductive film 229. In other words, the resonator array 200 can suppress the energy loss in the conductive film 229.

### [Modification 1]

In the above embodiment, the resonator array 200 is located in the ceiling wall 111. However, the resonator array may be located in the sidewall 112. In other words, the resonator array may be located in at least one of the ceiling wall 111 and the sidewall 112. In Modification 1, an example in which the resonator array is located in the sidewall 112 will be described with reference to FIGS. 24 and 25.

FIG. 24 is a perspective view schematically showing a sidewall of a processing chamber according to Modification 1. As shown in FIG. 24, the resonator array structure 300 is provided in an annular ring shape in the sidewall 112. In other words, at least a part of the sidewall 112 is formed as the resonator array structure 300, and the wall surface of the sidewall 112 on the processing space S side is formed of a dielectric. The resonator array structure 300 includes a plurality of resonators 201 arranged in the circumferential direction and the radial direction. Each resonator 201 includes a C-shaped ring member 211 and a dielectric 312 around the ring member 211. For example, the dielectric forming the resonator array structure 300 also serves as the dielectric 312. FIG. 24 shows the arrangement of the ring members 211 in the plurality of resonators 201. The ring members 211 are arranged in a direction in which the C-shape is visible in the vertical cross-sectional direction of the processing chamber 101.

The plurality of resonators 201 of the resonator array structure 300 are arranged radially with respect to the center of the processing chamber 101. Further, the plurality of resonators 201 are arranged on a plurality of circumferences 302 and 303, which are concentric circles, for example. In other words, the plurality of resonators 201 are arranged in a direction in which the holes of the ring member 211 intersect with the circumferences 302 and 303. The circumferences 302 and 303 are arranged in two stages in the vertical direction of the processing chamber 101.

FIG. 25 is a diagram showing an example of the relationship of the traveling direction of the electromagnetic waves, the resonator array structure, and the gas introducing nozzle according to Modification 1. As shown in FIG. 25, the resonator array structure 300 is located above a gas introducing nozzle 123a, i.e., on the ceiling wall 111 side, in the cross section of the sidewall 112.

The gas introducing nozzle 123a supplies a processing gas to the processing space S from the sidewall 112 in a direction of an arrow 123b. In other words, the gas introducing nozzle 123a is an example of one or multiple side gas injectors (SGI) attached to one or multiple openings formed in the sidewall 112. The gas introducing nozzle 123a may be provided in addition to the gas introducing nozzle 123 provided in the ceiling wall 111, or may be provided instead of the gas introducing nozzle 123.

In other words, the plasma processing apparatus 100 further includes the gas introducing nozzle 123a for introducing a gas for generating plasma into the processing chamber 101 in the sidewall 112. The resonator array structure 300 is located in the sidewall 112 to be positioned between the microwave transmitting plate 163 (microwave transmitting window) and the gas introducing nozzle 123a. In other words, the resonator array structure 300 is located in the sidewall 112 to be positioned between the connection portion between the ceiling wall 111 and the sidewall 112 and the gas introducing nozzle 123a.

As shown in FIG. 25, among the microwaves supplied from the microwave radiation mechanisms 143, the surface waves propagating through the plasma interface propagate from the ceiling wall 111 side along the sidewall 112 as indicated by an arrow 320 indicating the traveling direction of the electromagnetic waves. In the resonator array structure 300, the ring member 211 is located in a direction in which the C-shape is visible in the cross section of FIG. 25 (which is not shown), and the magnetic field of the electromagnetic waves propagating as indicated by the arrow 320 penetrate through the ring member 211. In other words, similarly to the resonator array structure 200, the resonator array structure 300 can suppress the propagation of the surface waves, so that the arrival of the electromagnetic waves at the gas introducing nozzle 123a can be suppressed. Therefore, in Modification 1, the occurrence of discharge and the generation of particles near the gas introducing nozzle 123a can be further suppressed.

The resonator array 300 may be combined with the resonator array 200 located in the ceiling wall 111. For example, when there is a restriction on the arrangement of the resonator array 200 in the ceiling wall 111, the restriction on the arrangement of the resonator array 200 can be compensated for by locating the resonator array 300 in the sidewall 112 corresponding to the location where the arrangement of the resonator array 200 is restricted. In other words, the resonator arrays 200 and 300 may be arranged separately. Further, the resonator arrays 200 and 300 may be provided in at least one of the ceiling wall 111 and the sidewall 112. In other words, the ceiling wall 111 or the sidewall 112 formed of a dielectric may exist between the resonator arrays 200 and 300 and the processing space S.

### [Modification 2]

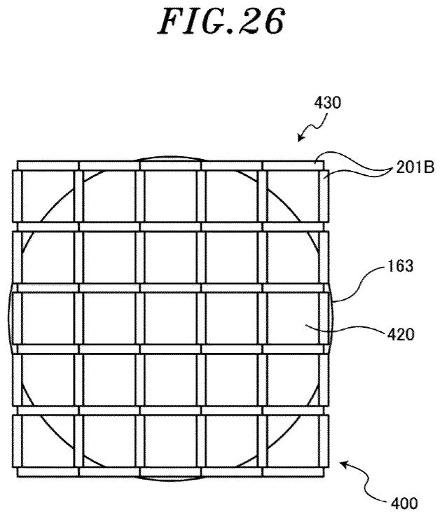

In the above embodiment, the microwaves supplied from the microwave radiation mechanisms 143 are supplied to the processing space S via the microwave transmitting plates 163. However, a resonator array structure may be further located on the bottom surface of the microwave transmitting plate 163. In Modification 2, an example in which a resonator array structure is further located on the bottom surface of the microwave transmitting plate 163 will be described with reference to FIG. 26.

FIG. 26 is a plan view showing an example of a configuration of a dielectric window and a resonator array structure according to Modification 2, which is viewed from below. In FIG. 26, the bottom surface of one of the microwave transmitting plates 163, which is a dielectric window, is illustrated in a disc shape. In Modification 2, as shown in FIG. 26, a resonator array structure 400 is provided on the bottom surface of the microwave transmitting plate 163, i.e., the positions of the ceiling wall 111 corresponding to the plurality of microwave radiation mechanisms 143. The resonator array structure 400 is formed by arranging a plurality of resonators 201B that can resonate with the magnetic field component of the microwaves and have sizes smaller than the wavelength of the microwaves. The resonator array structure 400 is located in the processing chamber 101. The bottom surface of the microwave transmitting plate 163 may be in contact with the resonator array structure 400, or may be separated therefrom.

By locating the resonator array structure 400 in the processing chamber 101, the microwaves supplied to the processing space S by the microwave radiation mechanisms 143 can be resonated with the plurality of resonators of the resonator array structure 400. Since the plurality of resonators resonate with the microwaves, the microwaves can be efficiently supplied to the processing space S of the processing chamber 101 and the magnetic permeability of the processing space S can become negative. When the magnetic permeability of the processing space S is negative, even if the electron density of the plasma produced in the processing space S reaches the cutoff density and the dielectric constant of the processing space S is negative, the refractive index becomes a real number according to the above Eq. (1), so that the microwaves can propagate in the processing space S. Accordingly, even if the electron density of the plasma produced in the processing space S reaches the cutoff density, the microwaves can propagate beyond the skin depth of the plasma and the power of the microwaves is efficiently absorbed by the plasma. As a result, high-density plasma can be produced over a wide range beyond the skin depth of the plasma. In other words, in accordance with the plasma processing apparatus 100 of Modification 2, the resonator array structure 400 is located in the processing chamber 101, so that the increase in the plasma over a wide area can be realized.

The resonator array structure 400 is formed by arranging the plurality of resonators 201B, which can resonate with the magnetic field component of the microwaves and have sizes smaller than the wavelength of the microwave, in a lattice pattern. The plurality of resonators 201B may be the resonators 201A shown in FIG. 7. In the example of FIG. 26, the resonators 201B are arranged such that cells 420 surrounded by the resonators 201B are formed in five columns in the X-axis direction and five rows in the Y-axis direction. In other words, the cells 420 are arranged in a 5×5 square array 430. In the array 430, the diameter of the microwave transmitting plate 163 and the length of one side of the resonator array structure 400 are approximately the same. Therefore, the cells 420 in the peripheral area are arranged across the microwave transmitting plates 163 and the ceiling wall 111, except for some of the cells 420 (first row, third row, first column, third row, fifth column, fifth row, and third column). When some of the cells 420 of the resonator array structure 400 are arranged across the microwave transmitting plates 163 and the ceiling wall 111, it is preferable that the ceiling wall 111 is a dielectric for propagation of the microwaves. In addition, the resonant frequency fᵣ of the resonator 201B of the resonator array structure 400 may be the same frequency as the resonant frequency fᵣ of the resonators 201 of the resonator array structures 200 and 300.

In Modification 2, by further providing the resonator array structure 400 on the bottom surface of the microwave transmitting plate 163, it is possible to further suppress the horizontal diffusion of the plasma from the microwave transmitting plates 163. In other words, the plasma is confined in the cells 420 of the resonator array 400, so that the interference between adjacent microwave radiation mechanisms 143 can be suppressed. In addition, the diffusion of the plasma to the sidewall 112 and the gas introducing nozzle 123 can be further suppressed. Therefore, the contamination of aluminum, yttrium, or the like due to the damage to the sidewall 112, or the abnormal discharge near the gas introducing nozzle 123 can be further suppressed. Further, the process speed can be stabilized by stabilizing the plasma discharge. Although not shown, the plurality of resonators 201B may be arranged on a base plate formed of a dielectric, and the resonator array 400 may include the base plate. In this case, the resonator array 400 can be easily installed at the ceiling wall 111. Further, in Modification 2, the surface waves are reflected by the resonator arrays 200 and 300 and return to the resonator array 400 while being absorbed by the plasma, so that the power efficiency of the resonator array 400 can be improved. In other words, in Modification 2, the electromagnetic waves (surface waves) at the portion distant from the resonator array structure 400 can be controlled by the resonator array structures 200 and 300.

### [Modification 3]

In the above embodiment, the resonant frequencies fᵣ of the plurality of resonators 201 in the resonator array structure 200 are the same for the circumferences 202 to 204. However, the frequencies may be different for the circumferences 202 to 204. For example, the resonant frequencies fᵣ of the plurality of resonators 201 in the circumference 202 may be 2.45 GHz, the resonant frequencies fᵣ of the plurality of resonators 201 in the circumference 203 may be 1.98 GHz, and the resonant frequencies fᵣ of the plurality of resonators 201 in the circumference 204 may be 915 MHz. Accordingly, it is possible to increase the frequency at which the propagation of the surface waves can be suppressed.

For example, the resonant frequencies fᵣ of the plurality of resonators 201 on the circumference 202 may be 910 MHz, the resonant frequencies fᵣ of the plurality of resonators 201 on the circumference 203 may be 915 MHz, and the resonant frequencies fᵣ of the plurality of resonators 201 on the circumference 204 may be 920 MHz. Accordingly, the radial distribution (diffusion) of plasma in the processing chamber 101 can be controlled.

As described above, in accordance with the present embodiment, the plasma processing apparatus 100 includes the processing chamber 101, the microwave generator (microwave output part 130), the microwave radiator (microwave radiation mechanism 143), the microwave transmitting window (microwave transmitting plate 163), and the resonator array structure (resonator array structures 200 and 300). The processing chamber 101 is configured to accommodate a substrate W, and define the processing space S by the ceiling wall 111, the sidewall 112, and the bottom wall 113. The microwave generator is configured to generate microwaves for generating plasma. The microwave radiator is provided above the ceiling wall 111 and configured to radiate microwaves toward the processing chamber 101. The microwave transmitting window is provided at a position of the ceiling wall 111 corresponding to the microwave radiator, and is formed of a dielectric. The resonator array structure is provided in at least one of the ceiling wall 111 and the sidewall 112, and is formed by arranging the plurality of resonators 201 that can resonate with the magnetic field component of the microwaves and each has a size smaller than the wavelength of the microwave. As a result, it is possible to suppress the electromagnetic waves propagating along the inner wall of the processing chamber 101.

Further, in accordance with the present embodiment, the resonator array structure is provided inside the wall. As a result, the propagation mode of the electromagnetic wave propagation path is eliminated, so that the propagation of the electromagnetic waves can be suppressed without directly installing a metal body in the electromagnetic wave propagation path.

Further, in accordance with the present embodiment, the resonator 201 includes two or more C-shaped ring members 211 made of a conductor. As a result, the resonator 201 can resonate with microwaves.

Further, in accordance with the present embodiment, the resonator 201 includes the dielectric 212 surrounding the ring member 211. As a result, the generation of particles can be suppressed.

Further, in accordance with the present embodiment, the ring member 211 can be inserted into the resonator 201 from the atmospheric side of the resonator array structure. As a result, the ring member 211 can be replaced without opening the processing chamber 101 to the atmosphere.

Further, in accordance with the present embodiment, the resonator array structure 200 is located in the ceiling wall 111 to be positioned between the microwave transmitting window and the connection portion between the ceiling wall 111 and the sidewall 112. As a result, the electromagnetic waves propagating along the inner wall of the processing chamber 101 can be suppressed.

In accordance with the present embodiment, the plurality of microwave radiators and the plurality of microwave transmitting windows are provided. Further, the resonator array structure 200 is located in the ceiling wall 111 to surround the plurality of microwave transmitting windows. As a result, the electromagnetic waves propagating along the inner wall of the processing chamber 101 from the plurality of microwave transmitting windows can be suppressed.

In accordance with the present embodiment, the plurality of microwave radiators and the plurality of microwave transmitting windows are provided. Further, the resonator array structure 200 is located in the ceiling wall 111 to surround the plurality of microwave transmitting windows. As a result, the electromagnetic waves propagating along the inner wall of the processing chamber 101 can be suppressed for each of the plurality of microwave transmitting windows. In accordance with Modification 1, the sidewall 112 further includes the gas introducing nozzle 123a for introducing a gas for generating plasma into the processing chamber 101. Moreover, the resonator array structure 300 is located in the sidewall 112 to be positioned between the microwave transmitting window and the gas introducing nozzle 123a. As a result, the propagation of the surface waves can be suppressed, thereby suppressing the arrival of the electromagnetic waves at the gas introducing nozzle 123a. Further, the occurrence of discharge or the generation of particles near the gas introducing nozzle 123a can be further suppressed.

Further, in accordance with Modification 1, the resonator array structure 300 is located in the sidewall 112 to be positioned between the connection portion between the ceiling wall 111 and the sidewall 112 and the gas introducing nozzle 123a. As a result, the propagation of the surface waves can be suppressed, thereby suppressing the arrival of electromagnetic waves at the gas introducing nozzle 123a. Further, the occurrence of discharge or the generation of particles near the gas introducing nozzle 123a can be further suppressed.

Further, in accordance with the present embodiment, the plurality of resonators 201 are arranged radially from the center of the processing chamber 101. As a result, the propagation mode of the electromagnetic waves (surface waves) propagating along the inner wall of the processing chamber 101 can be eliminated.

Further, in accordance with Modification 3, the resonator array structure includes the plurality of resonators 201 arranged on the plurality of concentric circumferences (circumferences 202 to 204, 302, and 303). Further, the plurality of resonators 201 have different resonant frequencies for the respective circumferences. As a result, the frequency at which the propagation of the surface waves can be suppressed can be increased. Further, the radial distribution (diffusion) of the plasma of the processing chamber 101 can be controlled.

Further, in accordance with the present embodiment, the resonator array structure has a relative magnetic permeability of −100 or less. As a result, when the conductive film 229 exists, the heat loss in the conductive film 229 can be suppressed.

Further, in accordance with the present embodiment, a conductive film (conductive film 229) is formed in the inner wall of the processing chamber 101. As a result, when the relative permeability of the resonator array structure is-100 or less, the heat loss in the conductive film 229 can be suppressed.

Further, in accordance with Modification 2, the resonator array structure (resonator array structure 400) is further located on the bottom surface of the microwave transmitting window. As a result, the power efficiency of the resonator array structure 400 can be improved.

It should be noted that the embodiments of the present disclosure are illustrative in all respects and are not restrictive. The above-described embodiments may be omitted, replaced, or changed in various forms without departing from the scope of the appended claims and the gist thereof.

Further, the present disclosure may have the following configurations.

(1)

A plasma processing apparatus comprising:
a processing chamber configured to accommodate a substrate and define a processing space by a ceiling wall, a sidewall, and a bottom wall;
a microwave generator configured to generate microwaves for producing plasma;
a microwave radiator provided above the ceiling wall and configured to radiate the microwaves toward the processing chamber;
a microwave transmitting window formed of a dielectric and provided at a position of the ceiling wall corresponding to the microwave radiator; and
a resonator array structure provided in at least one of the ceiling wall and the sidewall, the resonator array structure being formed by arranging a plurality of resonators that are configured to resonate with a magnetic field component of the microwaves and each having a size smaller than a wavelength of the microwaves.
   (2)

The plasma processing apparatus of (1), wherein the resonator array structure is provided inside the wall.

(3)

The plasma processing apparatus of (1) or (2), wherein the resonators include two or more C-shaped ring members made of a conductor.

(4)

The plasma processing apparatus of (3), wherein the resonator includes a dielectric surrounding the ring member.

(5)

The plasma processing apparatus of (3) or (4), wherein the ring member is inserted into the resonator from an atmospheric side of the resonator array structure.

(6)

The plasma processing apparatus of any one of (1) to (5), wherein the resonator array structure is located in the ceiling wall to be positioned between the microwave transmitting window and a connection portion between the ceiling wall and the sidewall.

(7)

The plasma processing apparatus of (6), wherein a plurality of the microwave radiators and a plurality of the microwave transmitting windows are provided, and the resonator array structure is located in the ceiling wall to surround the plurality of microwave transmitting windows.

(8)

The plasma processing apparatus of (6), wherein a plurality of the microwave radiators and a plurality of the microwave transmitting windows are provided, and a plurality of the resonator array structures are located in the ceiling wall to surround each of the plurality of microwave transmitting windows.

(9)

The plasma processing apparatus of any one of (1) to (8), further comprising:
a gas introducing nozzle provided in the sidewall to introduce a gas for producing the plasma into the processing chamber, and
the resonator array structure is located in the sidewall to be positioned between the microwave transmitting window and the gas introducing nozzle.
   (10)

The plasma processing apparatus of (9), wherein the resonator array structure is located in the sidewall to be positioned between a connection portion between the ceiling wall and the sidewall and the gas introducing nozzle.

(11)

The plasma processing apparatus of any one of (1) to (10), wherein the resonators are arranged radially from a center of the processing chamber.

(12)

The plasma processing apparatus of (11), wherein the resonator array structure is arranged on a plurality of circumferences that are concentric circles, and
the resonators have different resonant frequencies for the respective circumferences.
   (13)

The plasma processing apparatus of any one of (1) to (12), wherein the resonator array structure has a relative permeability of −100 or less.

(14)

The plasma processing apparatus of (13), wherein a conductive film is formed in an inner wall of the processing chamber.

(15)

The plasma processing apparatus of any one of (1) to (14), wherein the resonator array structure is further located on a bottom surface of the microwave transmitting window.

1. A plasma processing apparatus comprising:
a processing chamber configured to accommodate a substrate and define a processing space by a ceiling wall, a sidewall, and a bottom wall;
a microwave generator configured to generate microwaves for producing plasma;
a microwave radiator provided above the ceiling wall and configured to radiate the microwaves toward the processing chamber;
a microwave transmitting window formed of a dielectric and provided at a position of the ceiling wall corresponding to the microwave radiator; and
a resonator array structure provided in at least one of the ceiling wall and the sidewall, the resonator array structure being formed by arranging a plurality of resonators that are configured to resonate with a magnetic field component of the microwaves and each having a size smaller than a wavelength of the microwaves.

2. The plasma processing apparatus of claim 1, wherein the resonator array structure is provided inside the wall.

3. The plasma processing apparatus of claim 1, wherein the resonators include two or more C-shaped ring members made of a conductor.

4. The plasma processing apparatus of claim 3, wherein the resonator includes a dielectric surrounding the ring member.

5. The plasma processing apparatus of claim 3, wherein the ring member is inserted into the resonator from an atmospheric side of the resonator array structure.

6. The plasma processing apparatus of claim 1, wherein the resonator array structure is located in the ceiling wall to be positioned between the microwave transmitting window and a connection portion between the ceiling wall and the sidewall.

7. The plasma processing apparatus of claim 6, wherein a plurality of the microwave radiators and a plurality of the microwave transmitting windows are provided, and the resonator array structure is located in the ceiling wall to surround the plurality of microwave transmitting windows.

8. The plasma processing apparatus of claim 6, wherein a plurality of the microwave radiators and a plurality of the microwave transmitting windows are provided, and a plurality of the resonator array structures are located in the ceiling wall to surround each of the plurality of microwave transmitting windows.

9. The plasma processing apparatus of claim 1, further comprising:
a gas introducing nozzle provided in the sidewall to introduce a gas for producing the plasma into the processing chamber, and
the resonator array structure is located in the sidewall to be positioned between the microwave transmitting window and the gas introducing nozzle.

10. The plasma processing apparatus of claim 9, wherein the resonator array structure is located in the sidewall to be positioned between a connection portion between the ceiling wall and the sidewall and the gas introducing nozzle.

11. The plasma processing apparatus of claim 1, wherein the resonators are arranged radially from a center of the processing chamber.

12. The plasma processing apparatus of claim 11, wherein the resonator array structure is arranged on a plurality of circumferences that are concentric circles, and
the resonators have different resonant frequencies for the respective circumferences.

13. The plasma processing apparatus of claim 1, wherein the resonator array structure has a relative permeability of −100 or less.

14. The plasma processing apparatus of claim 13, wherein a conductive film is formed in an inner wall of the processing chamber.

15. The plasma processing apparatus of claim 1, wherein the resonator array structure is further located on a bottom surface of the microwave transmitting window.
